(19) United States
(12) Patent Application Publication
(10) Pub. No.: US 2007/0215378 A1
(43) Pub. Date: Sep. 20, 2007

(54) Circuit board

(75) Inventors: Takashi Kasahara, Osaka (JP); Yoshiaki Ukawa, Osaka (JP)

Correspondence Address: MORGAN LEWIS & BOCKIUS LLP, 1111 PENNSYLVANIA AVENUE NW, WASHINGTON, DC, 20004, US

(73) Assignee: Funai Electric Co., Ltd.

(21) Appl. No.: 11/717,152

(22) Filed: Mar. 13, 2007

(30) Foreign Application Priority Data
Mar. 14, 2006 (JP) 2006-068654

(51) Int. Cl. H05K 1/03

(52) U.S. Cl. 174/255

(57) ABSTRACT

A circuit board has, jointed together with adhesive, a single-layer flexible PCB having a through hole formed therein in the thickness direction and a rigid member having copper foil formed on one side of an insulating base member. A conductive pattern on the single-layer flexible PCB and the copper foil are electrically connected together via solder filling the through hole. Thus, with a low-cost circuit board, unnecessary electromagnetic emissions can be effectively reduced.

This application is based on Japanese Patent Application No. 2006-068654 filed on Mar. 14, 2006, the contents of which are hereby incorporated by reference.

### BACKGROUND OF THE INVENTION

1. Field of the Invention

The present invention relates to circuit boards employing PCBs (printed circuit boards).

2. Description of Related Art

Various PCBs (printed circuit boards) are used in electronic devices, and how to cope with unnecessary electromagnetic emissions from PCBs has been an issue: unnecessary electromagnetic emissions may incite other electronic devices to malfunctioning and therefore have to be reduced as effectively as possible.

One type of PCB known to be effective in reducing unnecessary electromagnetic emissions is so-called two-layer flexible PCBs. FIG. 3 is a cross-sectional view of part of a two-layer flexible PCB reinforced with a reinforcement board. The two-layer flexible PCB 6 is fabricated in the following manner. On both sides of an insulating base member 1 of polyimide, copper foil is bonded with adhesive 2; then, a through hole 5 is formed in the thickness direction. The inside of the through hole 5 is copper-plated, so that the copper foil layers on both sides are electrically connected together. Next, the copper foil is etched to form conductive patterns 3. Then, on the surface of the conductive patterns 3, insulating cover film 4 of polyimide is bonded with adhesive 2. Now, the two-layer flexible PCB 6 is complete. For reinforcement, the two-layer flexible PCB 6 is then bonded to an insulating reinforcement board 8 with adhesive 7.

In this structure, the upper and lower copper foil layers are formed into conductive patterns for grounding and power supply, and different parts of these are electrically connected together via through holes wherever necessary. Forming conductive patterns in two layers, one upper and another lower, in this way helps secure large areas for conductive patterns for grounding and power supply, and thus helps reduce unnecessary electromagnetic emissions. In addition, the conductive patterns for grounding and power supply thus formed in two layers act as a capacitor, and this too helps reduce unnecessary electromagnetic emissions.

Certainly, using a two-layer PCB as described above is effective in reducing unnecessary electromagnetic emissions. Inconveniently, however, doing so involves a difficult process of bonding copper foil on both sides of an insulating base member, resulting in high cost.

Incidentally, JP-A-2005-005413 discloses, as a technology related to the present invention, a composite circuit board comprising a flexible and a rigid circuit board.

### SUMMARY OF THE INVENTION

An object of the present invention is to provide a low-cost circuit board that is effective in reducing unnecessary electromagnetic emissions.

To achieve the above object, according to one aspect of the invention, a circuit board comprises: a single-layer flexible PCB having a first insulating base member and a conductive pattern formed on only one side of the first insulating base member, the single-layer flexible PCB having a hole formed therein in the thickness direction; and a rigid member having a second insulating base member and conductive foil formed on one side of the second insulating base member. Here, the first insulating base member and the conductive foil are joined together, and the conductive pattern and the conductive foil are electrically connected together via a conductor filling the hole.

With this structure, the use of the single-layer flexible PCB, which is inexpensive, helps greatly reduce cost as compared with the conventional structure requiring the use of a two-layer flexible PCB. Moreover, since no conductive pattern is formed in the conductive foil of the rigid member, large areas can be secured for the conductive patterns for grounding and power supply; in addition, these conductive patterns, along with the conductive foil, act as a capacitor. These effects combine to reduce unnecessary electromagnetic emissions as effectively as with the conventional structure involving a two-layer flexible PCB.

The conductor filling the hole may be, for example, solder. Thus, common soldering will do, and there is no need for special fabrication equipment.

According to another aspect of the invention, a circuit board comprises: a single-layer flexible PCB having a first insulating base member and a conductive pattern formed on only one side of the first insulating base member; and a rigid member having a second insulating base member and conductive foil formed on only one side of the second insulating base member. Here, the first insulating base member and the second insulating base member are joined together, and part of the conductive pattern is bent toward the conductive foil so as to be joined thereto and thereby electrically connected thereto.

With this structure, the use of the single-layer flexible PCB, which is inexpensive, helps greatly reduce cost as compared with the conventional structure requiring the use of a two-layer flexible PCB. Moreover, since no conductive pattern is formed in the conductive foil of the rigid member, large areas can be secured for the conductive patterns for grounding and power supply. Thus, it is possible to reduce unnecessary electromagnetic emissions as effectively as with the conventional structure involving a two-layer flexible PCB. Furthermore, the conductive foil may be kept in contact with, for example, the casing of an electronic device. This helps increase the area of the conductive pattern for grounding and thereby further reduce unnecessary electromagnetic emissions.

The conductive pattern may be joined to the conductive foil by, for example, being soldered thereto. Thus, common soldering will do, and there is no need for special fabrication equipment.

According to yet another aspect of the invention, an optical pickup comprises: a circuit board and a pickup base. Here, the circuit board includes: a single-layer flexible PCB having a first insulating base member and a conductive pattern formed on only one side of the first insulating base member; and a rigid member having a second insulating base member and conductive foil formed on only one side of the second insulating base member, wherein the first insulating base member and the second insulating base member are joined together, and wherein part of the conductive pattern is bent toward the conductive foil so as to be joined thereto and thereby electrically connected thereto. Moreover, the circuit board is fitted to the pickup base such that the conductive foil is kept in contact with the pickup base.

With this structure, it is possible to effectively reduce unnecessary electromagnetic emissions from disc drive devices and the like incorporating optical pickups.

### BRIEF DESCRIPTION OF THE DRAWINGS

FIG. 1 is a diagram showing the procedure for fabricating a circuit board according to a first embodiment of the invention;

FIG. 2 is a diagram showing the procedure for fabricating a circuit board according to a second embodiment of the invention; and

FIG. 3 is a diagram showing a two-layer flexible PCB reinforced with a reinforcement board.

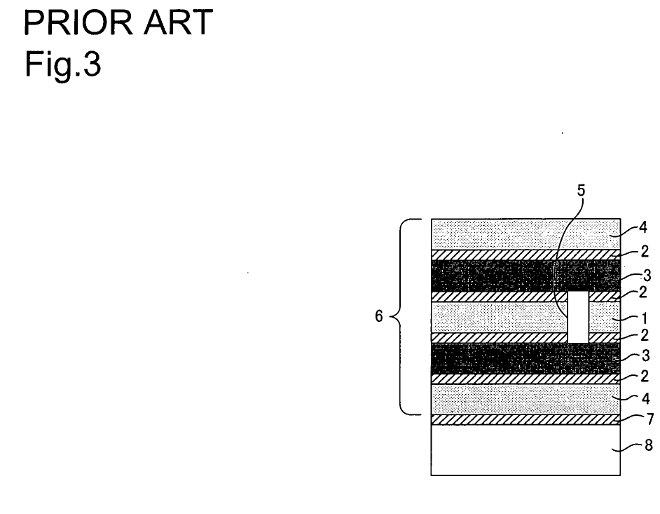

### DETAILED DESCRIPTION OF PREFERRED EMBODIMENTS

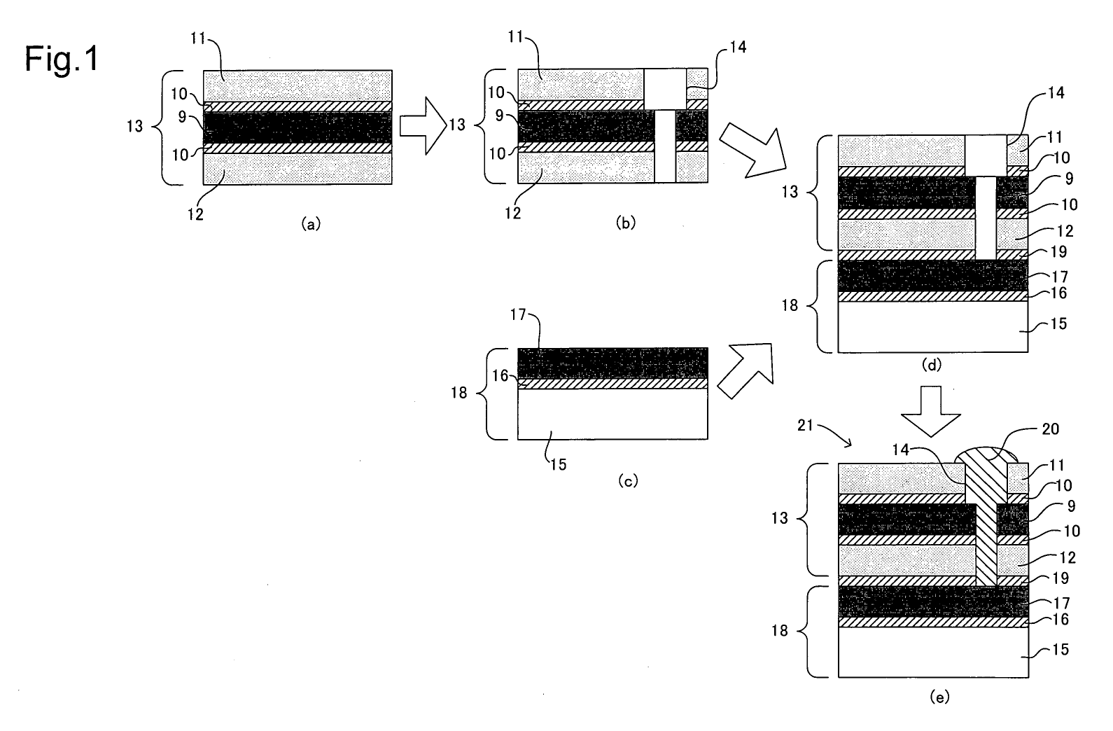

First Embodiment: A first embodiment of the invention will be described below with reference to the relevant drawing. FIG. 1 is a partly cross-sectional side view of a circuit board according to the first embodiment of the invention, and shows the procedure for fabricating the circuit board.

First, a so-called single-layer flexible PCB (printed circuit board) 13 as shown at (a) in FIG. 1 is fabricated in the following manner. On only one side of an insulating base member 12 of polyimide, copper foil is bonded with adhesive 10. Next, the copper foil is etched to form a conductive pattern 9. Then, on the surface of the conductive pattern 9, insulating cover film 11 of polyimide is bonded with adhesive 10. Now, the single-layer flexible PCB 13 is complete.

Next, as shown at (b) in FIG. 1, in the single-layer flexible PCB 13, a through hole 14 is formed in the thickness direction, so as to penetrate the conductive pattern 9. The through hole 14 is formed by, for example, punching or drilling.

Meanwhile, a rigid member 18 as shown at (c) in FIG. 1 is fabricated in the following manner. On only one side of an insulating base member 15 of glass epoxy, copper foil 17 is bonded with adhesive 16. Now, the rigid member 18 is complete. The insulating base member 15 may be formed of, other than glass epoxy, any material used to form a rigid circuit board, such as paper phenol or paper epoxy.

Next, as shown at (d) in FIG. 1, the surface of the copper foil 17 of the rigid member 18 and the surface of the insulating base member 12 of the single-layer flexible PCB 13 are bonded together with adhesive 19, so that the single-layer flexible PCB 13 and the rigid member 18 are put together. The adhesive 19 is in the form of film, and is previously perforated at the place where the through hole 14 is located, so that, when the single-layer flexible PCB 13 and the rigid member 18 are bonded together, no part of the adhesive 19 lies between the through hole 14 and the copper foil 17.

Then, cream solder is put in the through hole 14, is then melted at about 240° C., and is then hardened. This is a process generally called reflow soldering. Now, as shown at (e) in FIG. 1, the solder 20 filling the through hole 14 electrically connects together the conductive pattern 9 and the copper foil 17, and thus the circuit board 21 according to the first embodiment of the invention is complete.

With this circuit board 21 according to the invention, the use of the single-layer flexible PCB 13, which is inexpensive, helps greatly reduce cost as compared with the conventional structure requiring the use of a two-layer flexible PCB. Moreover, since no conductive pattern is formed in the copper foil 17 of the rigid member 18, large areas can be secured for the conductive patterns for grounding and power supply; in addition, these conductive patterns, along with the copper foil 17, act as a capacitor. These effects combine to reduce unnecessary electromagnetic emissions as effectively as with the conventional structure involving a two-layer flexible PCB.

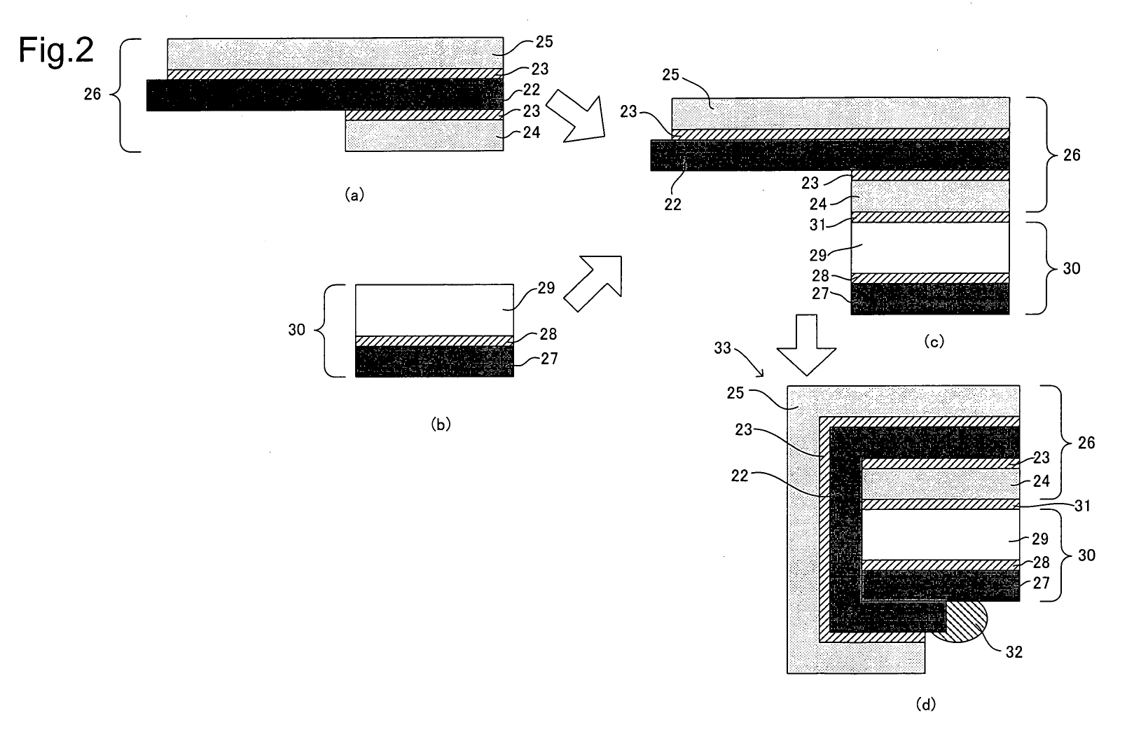

Second Embodiment: A second embodiment of the invention will be described below with reference to the relevant drawing. FIG. 2 is a partly cross-sectional side view of a circuit board according to the second embodiment of the invention, and shows the procedure for fabricating the circuit board.

First, a so-called single-layer flexible PCB (printed circuit board) 26 as shown at (a) in FIG. 2 is fabricated in the following manner. On only one side of an insulating base member 24 of polyimide, copper foil is bonded with adhesive 23. Next, the copper foil is etched to form a conductive pattern 22. Then, on the surface of the conductive pattern 22, insulating cover film 25 of polyimide is bonded with adhesive 23. Then, part of the insulating base member 24 and the adhesive 23 is removed so that the part of the conductive pattern 22 extending beyond the end of the insulating base member 24 is exposed. Now, the single-layer flexible PCB 26 is complete.

Meanwhile, a rigid member 30 as shown at (b) in FIG. 2 is fabricated in the following manner. On only one side of an insulating base member 29 of glass epoxy, copper foil 27 is bonded with adhesive 28. Now, the rigid member 30 is complete. The insulating base member 29 may be formed of, other than glass epoxy, any material used to form a rigid circuit board, such as paper phenol or paper epoxy.

Next, as shown at (c) in FIG. 2, the surface of the insulating base member 29 of the rigid member 30 and the surface of the insulating base member 24 of the flexible PCB 26 are bonded together with adhesive 31, so that the flexible PCB 26 and the rigid member 30 are put together.

Then, as shown at (d) in FIG. 2, the part of the conductive pattern 22 extending beyond the end of the insulating base member 24 is, along with the cover film 25 and the adhesive 23, bent toward the copper foil 27, and is joined to and thereby electrically connected to the copper foil 27 with solder 32. The solder 32 is applied using a soldering iron. Now, the circuit board 33 according to the second embodiment of the invention is complete.

With this circuit board 33 according to the invention, the use of the single-layer flexible PCB 26, which is inexpensive, helps greatly reduce cost as compared with the conventional structure requiring the use of a two-layer flexible PCB. Moreover, since no conductive pattern is formed in the copper foil 27 of the rigid member 30, large areas can be secured for the conductive patterns for grounding and power supply. Thus, it is possible to reduce unnecessary electromagnetic emissions as effectively as with the conventional structure involving a two-layer flexible PCB.

In a case where the circuit board 33 is used in, for example, an optical pickup for a disc drive apparatus, since the surface of the copper foil 27 of the rigid member 30 is exposed to the outside, the circuit board 33 can be fitted, with screws or the like, to the pickup base of the optical pickup such that the surface of the copper foil 27 is kept in contact with the pickup base. This helps increase the area of the conductive pattern for grounding and thereby further reduce unnecessary electromagnetic emissions. The same effect can be obtained by fitting the circuit board 33 to the casing of an electronic device such that the surface of the copper foil 27 is kept in contact with the casing.

What is claimed is:

1. A circuit board comprising:
a single-layer flexible PCB having
a first insulating base member and
a conductive pattern formed on only one side of the first insulating base member,
the single-layer flexible PCB having a hole formed therein in a thickness direction; and
a rigid member having
a second insulating base member and
conductive foil formed on one side of the second insulating base member,
wherein the first insulating base member and the conductive foil are joined together, and the conductive pattern and the conductive foil are electrically connected together via a conductor filling the hole.

2. The circuit board of claim 1,
wherein the conductor is solder.

3. A circuit board comprising:
a single-layer flexible PCB having
a first insulating base member and
a conductive pattern formed on only one side of the first insulating base member; and
a rigid member having
a second insulating base member and conductive foil formed on only one side of the second insulating base member,
wherein the first insulating base member and the second insulating base member are joined together, and part of the conductive pattern is bent toward the conductive foil so as to be joined thereto and thereby electrically connected thereto.

4. The circuit board of claim 3,
wherein the part of the conductive pattern is joined to the conductive foil by being soldered thereto.

5. An optical pickup comprising:
a circuit board including:
a single-layer flexible PCB having
a first insulating base member and
a conductive pattern formed on only one side of the first insulating base member; and
a rigid member having
a second insulating base member and
conductive foil formed on only one side of the second insulating base member,
the first insulating base member and the second insulating base member being joined together,
part of the conductive pattern being bent toward the conductive foil so as to be joined thereto and thereby electrically connected thereto; and
a pickup base,
wherein the circuit board is fitted to the pickup base such that the conductive foil is kept in contact with the pickup base.

6. The optical pickup of claim 5,
wherein the part of the conductive pattern is joined to the conductive foil by being soldered thereto.
